(19) United States
(12) Patent Application Publication
(10) Pub. No.: US 2025/0201172 A1
(43) Pub. Date: Jun. 19, 2025

(54) DISPLAY DEVICE

(71) Applicant: LG DISPLAY CO., LTD., Seoul (KR)

(72) Inventor: Jun Won LEE, Paju-si (KR)

(73) Assignee: LG DISPLAY CO., LTD., Seoul (KR)

(21) Appl. No.: 18/763,286

(22) Filed: Jul. 3, 2024

(30) Foreign Application Priority Data
Dec. 19, 2023 (KR) 10-2023-0185790

(51) Int. Cl. G09G 3/32; H01L 25/16

(52) U.S. Cl. CPC G09G 3/32; H01L 25/167; G09G 2300/0842; G09G 2300/0861; G09G 2320/0233; G09G 2320/064

(57) ABSTRACT

A display device includes a first sub-pixel including a light emitting element that emits light when driving power is applied and a first pixel driving circuit configured to drive the light emitting element by being controlled in a first control mode or a second control mode, and a second sub-pixel including a plurality of light emitting elements that emit light when driving power is applied and a second pixel driving circuit configured to drive the light emitting elements by being controlled in the first control mode or the second control mode. The first pixel driving circuit drives the light emitting element of the first sub-pixel by being controlled in the first control mode in a target luminance section, and the second pixel driving circuit drives the light emitting element of the second sub-pixel by being controlled in the second control mode in the target luminance section. According to the display device according to the present disclosure, it is possible to increase light efficiency and reduce power consumption.

### CROSS-REFERENCE TO RELATED APPLICATION

This application claims the priority of Korean Patent Application No. 10-2023-0185790, filed on Dec. 19, 2023, which is hereby incorporated by reference in its entirety.

### BACKGROUND

### Field of the Disclosure

The present disclosure relates to a display device. More specifically, the present disclosure relates to a display device using a light emitting diode as a light source.

### Description of the Background

Electroluminescent display devices include an inorganic light emitting diode display device (hereinafter referred to as an “LED display device”) in which an inorganic light emitting diode (hereinafter referred to as an “LED”) is disposed.

Recently, as an example of the inorganic LED display device, a micro-LED display device in which a micro-LED is disposed in pixels has been attracting attention as a next generation display device. The micro-LED may be an inorganic LED with a size of 100 μm or less. The micro-LED may be manufactured in a separate semiconductor process, transferred to pixel positions on a substrate for a display panel of the display device, and disposed in sub-pixels for each color.

### SUMMARY

The present disclosure is to provide a light emitting diode display device in which a main light emitting element and an auxiliary light emitting element are capable of simultaneously emitting light to implement a target luminance by dividing luminance range into a low luminance section and a high luminance section, adjusting the luminance by controlling the magnitude of a data voltage in the low luminance section, and adjusting the luminance by varying a pulse width in the high luminance section.

The present disclosure is not limited to those mentioned above, and other features not mentioned will be clearly understood by those skilled in the art from the following description.

A display device according to an aspect of the present disclosure includes a first sub-pixel including a light emitting element that emits light when driving power is applied and a first pixel driving circuit that drives the light emitting element by being controlled in a first control mode or a second control mode, and a second sub-pixel including a plurality of light emitting elements that emit light when driving power is applied and a second pixel driving circuit that drives the light emitting elements by being controlled in the first control mode or the second control mode, wherein the first pixel driving circuit may drive the light emitting element of the first sub-pixel by being controlled in the first control mode in a target luminance section, and the second pixel driving circuit may drive the light emitting element of the second sub-pixel by being controlled in the second control mode in the target luminance section.

The first sub-pixel may include a first light emitting element that emits light in the target luminance section, and the second sub-pixel may include a second light emitting element and a third light emitting element that emit light in the target luminance section.

The first sub-pixel may include a fourth light emitting element, and the first sub-pixel and the second sub-pixel may implement the same color.

Each of the first pixel driving circuit and the second pixel driving circuit may include a driving transistor including a gate electrode to which a data signal is input, a first electrode to which the driving power is applied, and a second electrode connected to the light emitting node, and a light emitting transistor including a gate electrode to which a light emitting control signal is input, a first electrode connected to the light emitting node, and a second electrode connected to a light emitting element.

The data signal may include a pulse amplitude modulation signal in an analog form, and the light emitting control signal may include a pulse width modulation signal in a digital form.

The pixel driving circuit controlled in the first control mode may adjust luminance of the light emitting element by the data signal, and the pixel driving circuit controlled in the second control mode may adjust luminance of the light emitting element by the light emitting control signal.

The target luminance section may include a first luminance section, a second luminance section having a luminance value greater than the first luminance section, and a third luminance section having a luminance value greater than the second luminance section, the first pixel driving circuit may drive the light emitting element by being controlled in the first control mode in the third luminance section, and the second pixel driving circuit may drive the light emitting element by being controlled in the second control mode in the third luminance section.

The first pixel driving circuit may drive the light emitting element by being controlled in the first control mode in the first luminance section, and the second pixel driving circuit may drive the light emitting element by being controlled in the first control mode in the first luminance section.

The first pixel driving circuit may drive the light emitting element by being controlled in the second control mode in the second luminance section, and the second pixel driving circuit may drive the light emitting element by being controlled in the second control mode in the second luminance section.

A light emitting control signal having a minimum pulse width may be applied to the first pixel driving circuit and the second pixel driving circuit at a point having a maximum luminance value of the first luminance section.

A light emitting control signal having a minimum pulse width may be applied to the first pixel driving circuit and the second pixel driving circuit at a point having a minimum luminance value of the second luminance section.

A light emitting control signal having a maximum pulse width may be applied to the first pixel driving circuit and the second pixel driving circuit at a point having a maximum luminance value of the second luminance section.

The light emitting control signal having the maximum pulse width may include a duty ratio of 100%.

A duty ratio of the light emitting control signal applied to the first pixel driving circuit and the second pixel driving circuit may increase as a luminance value in the second luminance section increases.

External quantum efficiency of the light emitting element included in each of the first pixel driving circuit and the second pixel driving circuit may increase as the luminance value in the first luminance section increases.

At least one of the first pixel driving circuit and the second pixel driving circuit may include the light emitting element having maximum external quantum efficiency in the second luminance section.

The external quantum efficiency of the light emitting element included in the first pixel driving circuit may decrease as the luminance value in the third luminance section increases.

A magnitude of a data voltage applied to the driving transistor of the first pixel driving circuit in the third luminance section, may be greater than a magnitude of the data voltage applied to the driving transistor of the first pixel driving circuit in the first luminance section.

The light emitting control signal having a maximum pulse width may be applied to the second pixel driving circuit at a point having a maximum luminance value of the third luminance section.

In the third luminance section, an average value of the external quantum efficiency of the light emitting element included in the second pixel driving circuit may be greater than an average value of the external quantum efficiency of the light emitting element included in the first pixel driving circuit.

Specific details of other aspects are included in the detailed description and drawings.

### BRIEF DESCRIPTION OF THE DRAWINGS

The above and other objects, features and advantages of the present disclosure will become more apparent to those of ordinary skill in the art by describing exemplary aspects thereof in detail with reference to the accompanying drawings, in which:

FIG. 1 is a view showing a display device according to one aspect of the present disclosure;

FIG. 2 is a partially enlarged view showing area A of FIG. 1;

FIG. 3 is a partially enlarged view showing a pixel area of FIG. 2;

FIG. 4 is a cross-sectional view along line I-I′ in FIG. 3;

FIG. 5 is a cross-sectional view showing a structure of a light emitting element;

FIG. 6 is a graph showing external quantum efficiency (hereinafter referred to as EQE) according to luminance of a light emitting element;

FIG. 7 is a graph showing luminance of a light emitting element according to a voltage supplied to the light emitting element;

FIG. 8 is a circuit diagram showing a pixel driving circuit connected to a light emitting element according to an aspect of the present disclosure;

FIG. 9 is a circuit diagram specifically showing the pixel driving circuit according to an aspect of the present disclosure;

FIG. 10 is a graph showing control modes according to luminance sections in a single chip sub-pixel; and

FIG. 11 is a graph showing control modes according to luminance sections in a dual chip sub-pixel.

### DETAILED DESCRIPTION

Advantages and features of the present disclosure and methods for achieving them will become clear with reference to aspects described below in detail in conjunction with the accompanying drawings. However, the present disclosure is not limited to the aspects disclosed hereafter and will be embodied in various different forms, and the present aspects are provided merely to make the disclosure of the present disclosure complete and to fully inform those skilled in the art of the scope of the present disclosure, and the present disclosure is only defined by the scope of the claims.

Since shapes, sizes, proportions, angles, numbers, and the like disclosed in the drawings to illustrate aspects of the present disclosure are exemplary, the present disclosure is not limited to those shown. In addition, in describing the present disclosure, when it is determined that the detailed description of a related known technology may unnecessarily obscure the gist of the present disclosure, detailed description thereof will be omitted.

When “includes,” “has,” “consists of,” and the like mentioned in the present disclosure are used, other parts may be added unless “only” is used. When a component is expressed in the singular, the plural is included unless otherwise specifically stated.

When interpreting a component, it is interpreted to include a margin of error unless otherwise specifically stated.

In the case that a positional relationship is described, when the positional relationship of two parts is described such as “on,” “above,” “under,” or “beside,” unless “right” or “directly” is used, one or more other parts may be located between the two parts.

When an element or layer is referred to as being on another element or layer, this includes both being directly on the other element or layer and being on it with another layer or element interposed in therebetween.

In addition, “first,” “second,” and the like are used to describe various components, but the components are not limited by these terms. These terms are only used to distinguish one component from another component. Therefore, a first component mentioned hereinafter may also be a second component within the technical spirit of the present disclosure.

Throughout the disclosure, the same reference numerals refer to the same elements.

A size and thickness of each component shown in the drawings are shown for illustrative purposes only, and the present disclosure is not necessarily limited to the shown sizes and thicknesses of the components.

Each feature of various aspects of the present disclosure may be combined or mixed partially or entirely, various types of technological interworking and driving are possible, and each aspect may be implemented independently of the others or they may be implemented together in an associated relationship.

In a display device according to the present disclosure, a pixel driving circuit may include a plurality of transistors. The transistors may be an oxide TFT containing an oxide semiconductor or a low temperature poly silicon (LTPS) TFT including LTPS.

The transistor is a three-electrode element including a gate, a source, and a drain. The source is an electrode that supplies carriers to the transistor. In the transistor, the carriers begin to flow from the source. The drain is an electrode from which the carriers exit the transistor. In the transistor, carriers flow from the source to the drain.

In the case of an n-channel transistor, since the carriers are electrons, a source voltage is lower than a drain voltage so that the electrons may flow from the source to the drain. In the n-channel transistor, the current flows from the drain to the source. In the case of a p-channel transistor, since the carriers are holes, the source voltage is higher than the drain voltage so that the holes may flow from the source to the drain. In the p-channel transistor, a current flows from the source to the drain because the holes flow from the source to the drain. It should be noted that the source and drain of the transistor are not fixed. For example, the source and the drain may be changed depending on an applied voltage. Therefore, the disclosure is not limited by the source and drain of the transistor. In the following description, the source and drain of the transistor are referred to as “first and second electrodes.”

Hereinafter, various aspects of the present disclosure will be described in detail with reference to the accompanying drawings.

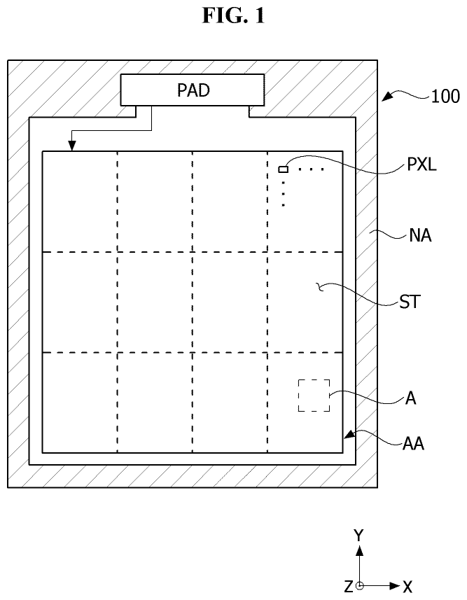

FIG. 1 is a view showing a display device according to one aspect of the present disclosure.

Referring to FIG. 1, a display device 10 according to one aspect of the present disclosure may include a display panel on which a display area AA on which images are displayed or screens are disposed, pixels PXL disposed on the display panel, and a pixel driving circuit that drives the pixels PXL. The pixel driving circuit may be embedded in the display panel.

The display panel may include the display area AA on which images are displayed and a non-display area NA on which the images are not displayed. Various lines and driving circuits may be mounted and a pad portion PAD to which integrated circuits, printed circuits, and the like are connected may be disposed in the non-display area NA.

The pixel PXL disposed in the display area AA may be formed of a plurality of light emitting elements. The plurality of light emitting elements may be micro-sized inorganic light emitting elements or nano-sized inorganic light emitting elements. The inorganic light emitting elements may be grown on a silicon wafer and then bonded to the display panel through a transfer process.

The transfer process of the light emitting elements may be performed for each pre-defined area. FIG. 1 shows that the display area AA is divided into 12 transfer zones ST, but the size or number of divisions of the transfer zones is not limited thereto. The transfer process may be performed sequentially or simultaneously in a first transfer zone ST to a twelfth transfer zone ST. In the transfer zone ST, a blue light emitting element, a green light emitting element, and a red light emitting element may be transferred sequentially, but are not limited thereto.

In the non-display area NA, a data driving circuit or a gate driving circuit may be disposed, and lines to which control signals for controlling such driving circuits are supplied may be disposed. The control signals may include various timing signals including clock signals, input data enable signals, and synchronization signals. The control signals may be transmitted and received via the pad portion PAD.

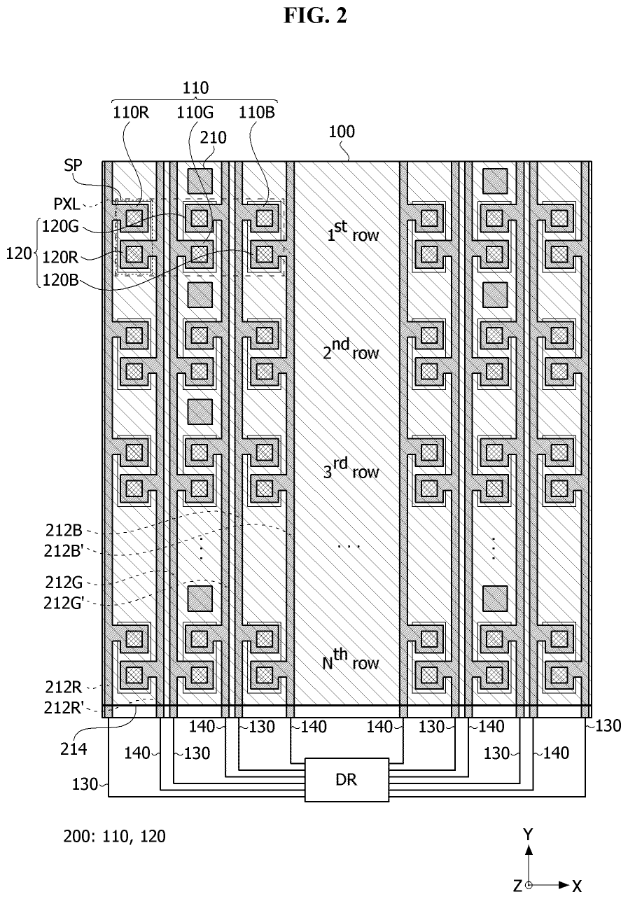

FIG. 2 is a partially enlarged view showing area A of FIG. 1.

Referring to FIG. 2, a display device according to one aspect of the present disclosure may include a display panel 100 and a pixel driving portion DR for controlling the display panel 100.

Each pixel disposed on the display panel 100 may include a plurality of sub-pixels SP. The plurality of sub-pixels SP included in one pixel may include a plurality of main light emitting elements 110 and auxiliary light emitting elements 120 having different colors. The plurality of sub-pixels SP may be sequentially disposed in a first direction (e.g., an X-axis direction) and a second direction (e.g., a Y-axis direction) intersecting the first direction. A plurality of light emitting elements 200 of the same color may be disposed in the sub-pixel SP of the display area AA. For example, the plurality of sub-pixels SP may include a red sub-pixel, a green sub-pixel, and a blue sub-pixel. The red sub-pixel may include a red main light emitting element 110R and a red auxiliary light emitting element 120R that emit light of a red wavelength. The green sub-pixel may include a green main light emitting element 110G and a green auxiliary light emitting element 120G that emit light of a green wavelength. The blue sub-pixel may include a blue main light emitting element 110B and a blue auxiliary light emitting element 120B that emit light of a blue wavelength.

One pixel PXL may include a plurality of sub-pixels SP. According to an aspect, since one sub-pixel SP includes at least two light emitting elements, the main light emitting element 110 and the auxiliary light emitting element 120 may be driven simultaneously. Accordingly, luminance of the sub-pixel SP may be up to twice the luminance from driving only one light emitting element, and luminance of the pixel PXL may be adjusted. However, the present disclosure is not necessarily limited thereto, and one sub-pixel SP may include only one light emitting element.

The pixels PXL may be driven by the pixel driving portion DR. The pixel driving portion DR may be a driving driver manufactured using a metal-oxide-silicon field transistor (MOSFET) manufacturing process. The pixel driving portion DR may be a micro driver. The driving driver may drive the sub-pixel including the pixel driving circuit.

The pixel driving portion DR may drive a plurality of pixels by receiving a driving voltage, an image signal (digital signal), a synchronization signal synchronized with the image signal, etc., and outputting an anode voltage and a cathode voltage of the light emitting element 200. The driving voltage may be a high potential voltage EVDD. The cathode voltage may be a low potential voltage EVSS commonly applied to the pixels. The anode voltage may be a voltage corresponding to a pixel data value of the image signal. The pixel driving portion DR may be disposed in the non-display area NA or under the display area AA. When the pixel driving portion DR is disposed under the display area AA, one pixel driving portion DR may be disposed in each light emitting area. The light emitting area may include at least one pixel PXL. For example, the light emitting area may include at least a few dozen or more pixels PXL.

A high potential voltage may be applied to a circuit driving each of the light emitting elements 110R, 110G, 110B, 120R, 120G, and 120B via the signal lines 130 and 140. The signal lines 130 and 140 and a first electrode 212 may be formed of an integrated electrode pattern during an electrode patterning process.

As an example, a first signal line 130 may be connected to each of a first electrode 212R of the red main light emitting element 110R, a first electrode 212G of the green main light emitting element 110G, and a first electrode 212B of the blue main light emitting element 110B. A second signal line 140 may be connected to each of a first electrode 212R′ of the red auxiliary light emitting element 120R, a first electrode 212G′ of the green auxiliary light emitting element 120G, and a first electrode 212B′ of the blue auxiliary light emitting element 120B. The number of signal lines 130 and 140 may vary according to the number of light emitting elements that the sub-pixel SP includes. For example, when one sub-pixel includes only one light emitting element, the number of signal lines 130 and 140 may be reduced by half, but the present disclosure is not limited thereto.

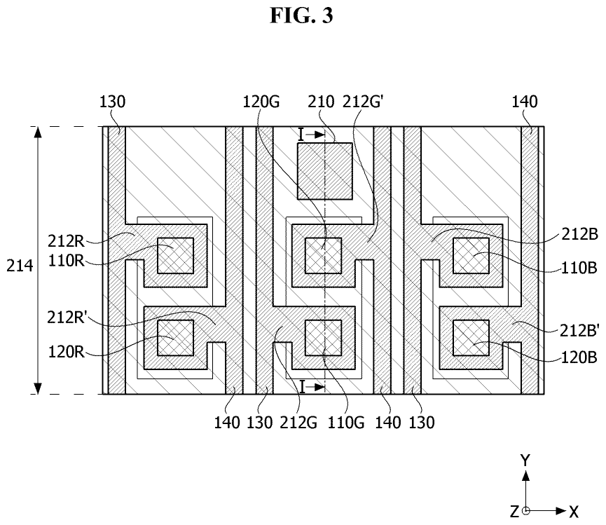

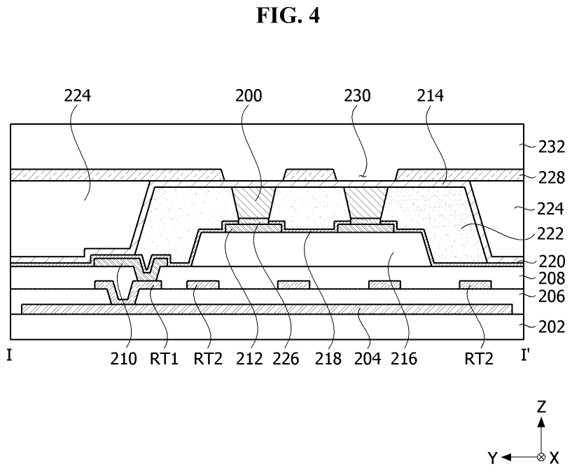

FIG. 3 is a partially enlarged view showing a pixel area of FIG. 2. FIG. 4 is a cross-sectional view along line I-I′ in FIG. 3.

Referring to FIGS. 2 to 4, the plurality of first electrodes 212 may each be disposed under the light emitting element 200 and may be selectively connected to the plurality of signal lines 130 and 140. A high potential voltage may be applied to a pixel driving circuit 204 through the signal lines 130 and 140. The signal lines 130 and 140 and the first electrode 212 may be formed of an integrated electrode pattern during an electrode patterning process. The first electrode 212 may be an anode electrode that is disposed for each column and applies an anode voltage to the light emitting element 200 continuously disposed in the second direction (e.g., the Y-axis direction).

A second electrode 214 may be a cathode electrode that is disposed for each row and applies a cathode voltage to the light emitting element 200 continuously disposed in the first direction (e.g., the X-axis direction) intersecting the second direction.

The plurality of second electrodes 214 may be disposed to be spaced apart from each other in the second direction (Y-axis direction). The plurality of second electrodes 214 may receive the cathode voltage through a contact electrode 210. The plurality of second electrodes 214 may each be electrically connected to the contact electrode 210. However, the present disclosure is not limited thereto, and the second electrode 214 is not divided into a plurality of second electrodes and may be formed as one electrode layer serving as a common electrode.

The display device according to an aspect may include the plurality of first electrodes 212 and the contact electrode 210 disposed on a substrate 202, the plurality of light emitting elements 200 disposed on the plurality of first electrodes 212, a first optical layer 222 disposed between the plurality of light emitting elements 200, and the second electrode 214 disposed on the plurality of light emitting elements 200.

The substrate 202 may be formed of plastic having flexibility. For example, the substrate 202 may be manufactured as a single layer or multilayered substrate of a material including one of polyimide, polyethylene terephthalate, polyethylene naphthalate, polyarylate, polysulfone, or a cyclic-olefin copolymer, but is not limited thereto. For example, the substrate 202 may be a ceramic substrate or a glass substrate.

The pixel driving circuit 204 may be disposed in the display area AA on the substrate 202. The pixel driving circuit 204 may include a plurality of thin film transistors using an amorphous silicon semiconductor, a polycrystalline silicon semiconductor, or an oxide semiconductor.

The pixel driving circuit 204 may include at least one driving thin film transistor, at least one switching thin film transistor, and at least one storage capacitor. When the pixel driving circuit 204 includes the plurality of thin film transistors, the pixel driving circuit 204 may be formed by a TFT manufacturing process on the substrate 202. In an aspect, the pixel driving circuit 204 may be a plurality of thin film transistors electrically connected to the light emitting element 200 as a general concept.

A buffer layer 206 covering the pixel driving circuit 204 may be disposed on the substrate 202. The buffer layer 206 may be formed of an organic insulating material, for example, photosensitive photo acryl or photosensitive polyimide, but is not limited thereto.

The buffer layer 206 may be provided as multiple layers formed by stacking an inorganic insulating material, for example, silicon nitride (SiNₓ) or silicon oxide (SiO₂) and provided as multiple layers formed by stacking an organic insulating material and an inorganic insulating material.

An insulating layer 208 may be disposed on the buffer layer 206. The insulating layer 208 may be formed of an organic insulating material, for example, photosensitive photo acryl or photosensitive polyimide, but is not limited thereto.

Connection lines RT1 and RT2 may be disposed on the buffer layer 206. The connection lines RT1 and RT2 may be connected through corresponding signal lines 130 and 140 or may be connected to the signal lines 130 and 140. The connection lines RT1 and RT2 may include a plurality of line patterns disposed on different layers with one or more insulating layers interposed therebetween. The line patterns disposed on the different layers may be electrically connected through a contact hole passing through the insulating layer.

A plurality of bank patterns 216 may be disposed on the insulating layer 208. At least one light emitting element 200 may be disposed on each of the bank patterns 216. For example, the main light emitting element 110 may be disposed on a first bank pattern 216 and the auxiliary light emitting element 120 may be disposed on a second bank pattern 216.

The bank pattern 216 may be formed of an organic insulating material, for example, photosensitive photo acryl or photosensitive polyimide, but is not limited thereto. The bank pattern 216 may guide an attachment position of the light emitting element 200 in a transfer process of the light emitting elements 200. The bank pattern 216 may be omitted.

The light emitting elements 200 may each be mounted on a solder pattern 226 on the first electrode 212. One pixel PXL may include the light emitting elements 200 of three colors. The red main light emitting element 110R may be a red light emitting element, the green main light emitting element 110G may be a green light emitting element, and the blue main light emitting element 110B may be a blue light emitting element. Two light emitting elements of the same color may be mounted in each pixel.

The first optical layer 222 may cover the plurality of light emitting elements 200 and the bank patterns 216. Accordingly, the first optical layer 222 may cover spaces between the plurality of light emitting elements 200 and between the plurality of bank patterns 216. The first optical layer 222 may extend in the first direction (e.g., the X-axis direction) and may be spaced apart in the second direction (e.g., the Y-axis direction) to be separated between pixel rows.

The first optical layer 222 may include an organic insulating material in which fine metal particles such as titanium dioxide particles are dispersed. Light emitted from the plurality of light emitting elements 200 may be scattered by fine metal particles dispersed in the first optical layer 222 and emitted to the outside.

The second electrode 214 may be disposed on the plurality of light emitting elements 200. The second electrode 214 may be commonly connected to the plurality of pixels PXL. The second electrode 214 may be a thin electrode through which light is transmitted. The second electrode 214 is a transparent conductive oxide (TCO), and may be formed of, for example, indium tin oxide (ITO), but is not limited thereto.

The second electrode 214 may extend in the first direction (e.g., the X-axis direction) and may be spaced apart in the second direction (e.g., the Y-axis direction). The second electrode 214 may be disposed on an upper surface of the light emitting element 200 and an upper surface of the first optical layer 222, may be in contact with the contact electrode 210, and may be disposed on a side surface of the first optical layer 222.

A second optical layer 224 may be formed of an organic insulating material surrounding the first optical layer 222. The second optical layer 224 may be disposed on the insulating layer 208 together with the first optical layer 222. The first optical layer 222 and the second optical layer 224 may include the same material (e.g., siloxane). For example, the first optical layer 222 may be siloxane containing titanium oxide (TiOx), and the second optical layer 242 may be siloxane not containing titanium oxide (TiOx). However, the present disclosure is not limited thereto, and the first optical layer 222 and the second optical layer 224 may be formed of the same material or may be formed of different materials.

The second optical layer 224 may cover at least a portion of the second electrode 214. An upper surface of the second optical layer 224 and an upper surface of the second electrode 214 may form the same plane (e.g., an XY plane). The first optical layer 222 and the second optical layer 224 may function as planarization layers. Therefore, since there is no step on a surface on which a black matrix 228 is formed, patterns of the black matrix 228 may be easily formed on the first optical layer 222 and the second optical layer 224. However, the present disclosure is not limited thereto, and the upper surfaces of the second optical layer 224 and the second electrode 214 may have different heights.

The black matrix 228 may be made of an organic insulating material to which a black pigment is added. The second electrode 214 may be in contact with the contact electrode 210 under the black matrix 228. A transmission hole 230 through which light emitted from the light emitting element 200 is emitted to the outside may be formed between the patterns of the black matrix 228. The black matrix 228 may solve a mixing problem of light emitted from neighboring light emitting elements 200 by the first optical layer 222.

A cover layer 232 may be made of an organic insulating material that covers the black matrix 228 and the second electrode 214.

The contact electrode 210 may be electrically connected to the first connection line RT1 disposed thereunder, and the first connection line RT1 may be connected to the pixel driving circuit 204. The cathode voltage may be applied to the second electrode 214 through the contact electrode 210. The first electrode 212 may be electrically connected to the second connection line RT2.

The pixel driving circuit 204 may be disposed under the contact electrode 210. When the pixel driving circuit 204 is a driving driver, a plurality of driving drivers may be disposed in the display panel.

A passivation layer 220 may expose the contact electrode 210 to electrically connect the contact electrode 210 and the second electrode 214. In addition, the passivation layer 220 may insulate the signal lines 130 and 140 from the second electrode 214.

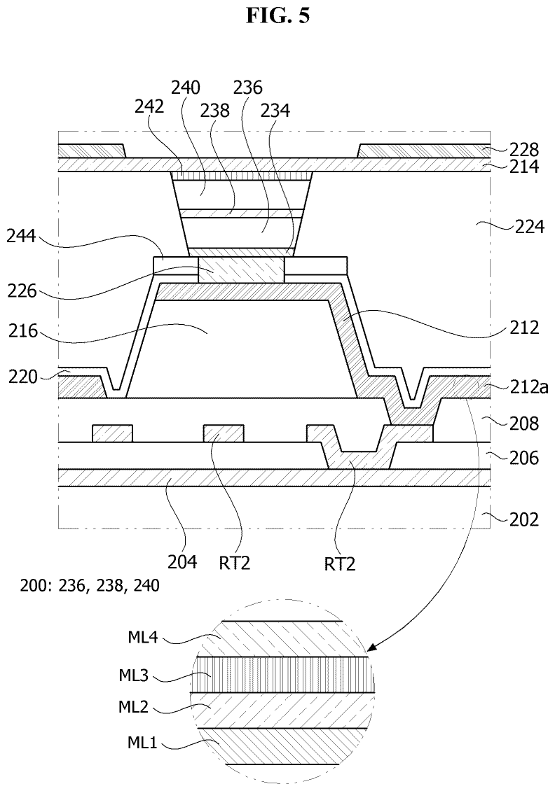

FIG. 5 is a cross-sectional view showing a structure of a light emitting element.

Referring to FIG. 5, a connection portion 212a of the first electrode 212 may extend to one side surface of the bank pattern 216 and may be electrically connected to the connection line RT2 disposed on the buffer layer 206.

The first electrode 212, the connection portion 212a, the signal lines, and/or the connection lines RT1 and RT2 may include a single or multiple metal layer of a material including one of titanium (Ti), molybdenum (Mo), and aluminum (Al). The first electrode 212, the connection portion 212a, the signal lines, and/or the connection lines RT1 and RT2 may be formed in a multi-layer structure including a first layer ML1, a second layer ML2, a third layer ML3, and a fourth layer ML4.

The first layer ML1 and the third layer ML3 may include titanium (Ti) or molybdenum (Mo). The second layer ML2 may include aluminum (Al). The fourth layer ML4 may include a transparent conductive oxide layer such as indium tin oxide (ITO) and indium zinc oxide (IZO) that has good adhesion (such as with the solder pattern 226), corrosion resistance, and acid resistance.

The first layer ML1, the second layer ML2, the third layer ML3, and the fourth layer ML4 may be sequentially deposited and then patterned by performing a photolithography process and an etching process.

The passivation layer 220 may be disposed on the first electrode 212 and the signal lines and expose the solder pattern 226.

The light emitting element 200 may include a first conductive semiconductor layer 236, an active layer 238, and a second conductive semiconductor layer 240. A first driving electrode 234 may be disposed under the first conductive semiconductor layer 236 and a second driving electrode 242 may be disposed on the second conductive semiconductor layer 240.

The light emitting element 200 may be formed on a silicon wafer using a metal organic chemical vapor deposition (MOCVD) method, a chemical vapor deposition (CVD) method, a plasma-enhanced chemical vapor deposition (PECVD) method, a molecular beam epitaxy (MBE) method, a hydride vapor phase epitaxy (HVPE) method, a sputtering method, etc.

The first conductive semiconductor layer 236 may be implemented with a compound semiconductor such as a group III-V or group II-VI compound semiconductor, and may be doped with a first dopant. The first conductive semiconductor layer 236 may be formed of a semiconductor material with a composition formula of Alₓ₁In_{y1}Ga_{(1-x1-y1)}N (0≤x1≤1, 0≤y1≤1, 0≤x1+y1≤1), or a material including one of InAlGaN, AlGaAs, GaP, GaAs, GaAsP, and AlGaInP, but is not limited thereto. When the first dopant is an n-type dopant such as Si, Ge, Sn, Se, Te, etc., the first conductive semiconductor layer 236 may be an n-type nitride semiconductor layer. However, when the first dopant is a p-type dopant, the first conductive semiconductor layer 236 may be a p-type nitride semiconductor layer.

The active layer 238 is a layer in which electrons (or holes) injected through the first conductive semiconductor layer 236 meet holes (or electrons) injected through the second conductive semiconductor layer 240. The active layer 238 may transition to a lower energy level as the electrons and holes recombine, and may generate light with a corresponding wavelength.

The active layer 238 may have any one of a single well structure, a multi-well structure, a single quantum well structure, a multi quantum well (MQW) structure, a quantum dot structure, or a quantum line structure, and the structure of the active layer 238 is not limited thereto. The active layer 238 may generate light in a visible light wavelength range. As an example, the active layer 238 may output light in a wavelength range of any one of blue, green, and red.

The second conductive semiconductor layer 240 may be disposed on the active layer 238. The second conductive semiconductor layer 240 may be implemented with a compound semiconductor such as a group III-V or group II-VI compound semiconductor, and the second conductive semiconductor layer 240 may be doped with a second dopant. The second conductive semiconductor layer 240 may be formed of a semiconductor material with a composition formula of Inₓ₂Al_{y2}Ga_{1-x2-y2}N (0≤x2≤1, 0≤y2≤1, 0≤x2+y2≤1) or a material including one of AlInN, AlGaAs, GaP, GaAs, GaAsP, and AlGaInP. When the second dopant is a p-type dopant such as Mg, Zn, Ca, Sr, or Ba, the second conductive semiconductor layer 240 with which the second dopant is doped may be a p-type semiconductor layer. When the second dopant is an n-type dopant, the second conductive semiconductor layer 240 may be an n-type nitride semiconductor layer.

A reflective layer 244 may be disposed under the light emitting element 200. The reflective layer 244 may have a structure in which a reflective material is dispersed in a resin layer, but is not limited thereto. The reflective layer 244 may be manufactured in various structures. Light emitted from the active layer 238 is reflected upward due to the reflective layer 244, thereby increasing light extraction efficiency.

Although the aspect is described as a vertical structure in which the driving electrodes 234 and 242 are disposed on and under the light emitting member, the light emitting element may have a lateral structure or a flip chip structure in addition to the vertical structure.

The pixel driving circuit 204 may apply an anode voltage to the main light emitting element 110 and the auxiliary light emitting element 120 via the second connection line RT2. The pixel driving circuit 204 may apply a cathode voltage to the main light emitting element 110 and the auxiliary light emitting element 120 via the first connection line RT1 and the second electrode 214.

The pixel driving circuit 204 may control luminance by driving only one of the main light emitting element 110 or the auxiliary light emitting element 120. The pixel driving circuit 204 may control luminance by driving both the main light emitting element 110 and the auxiliary light emitting element 120. In an aspect, the pixel driving circuit 204 may control luminance by simultaneously driving the main light emitting element 110 and the auxiliary light emitting element 120. When the main light emitting element 110 is darkened, the pixel driving circuit 204 may control luminance by driving only the auxiliary light emitting element 120.

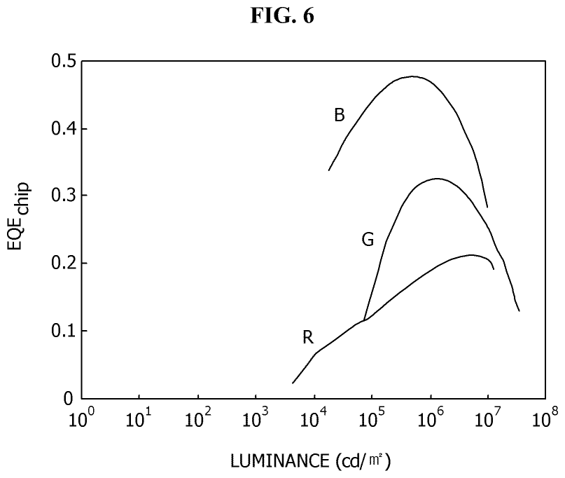

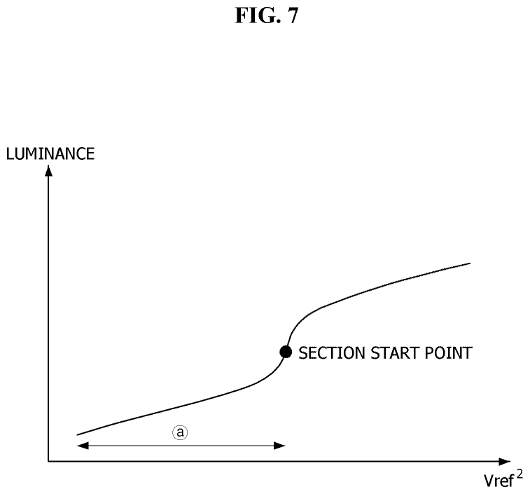

FIG. 6 is a graph showing external quantum efficiency (hereinafter referred to as EQE) according to luminance of a light emitting element. FIG. 7 is a graph showing luminance of a light emitting element according to a voltage supplied to the light emitting element.

Referring to FIG. 6, EQE of each light emitting element that emits red (R), green (G), and blue (B) light may have a maximum value. Each of the light emitting elements may have maximum luminous efficiency at the maximum value of EQE.

Referring to FIG. 7, a luminance as a function of voltage supplied to the light emitting element may include a section (a) of low luminance and a point (or section) (b) at which luminance increases and the slope of the curve changes rapidly. The point (or section) (b) at which the slope of the curve changes rapidly is the point of maximum luminous efficiency of the light emitting element and is the point with the maximum value of EQE of the light emitting element.

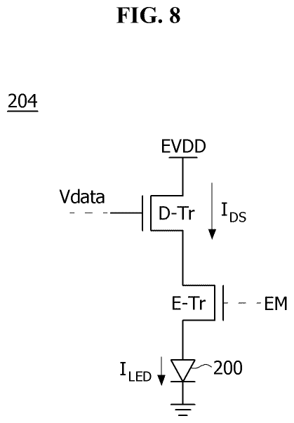

FIG. 8 is a circuit diagram showing a pixel driving circuit connected to a light emitting element according to an aspect of the present disclosure.

Referring to FIG. 8, the pixel driving circuit 204 may include a driving transistor D-Tr and a light emitting transistor E-Tr. The pixel driving circuit 204 may further include a plurality of power lines, a plurality of scan lines, reference voltage lines, data voltage lines, and light emitting control lines.

The driving transistor D-Tr and the light emitting transistor E-Tr may be implemented as n-channel TFTs. The n-channel TFTs may be turned on in response to a gate high voltage and turned off in response to a gate low voltage. A p-channel TFT may be turned on in response to the gate low voltage and turned off in response to the gate high voltage. Hereinafter, it is explained on the assumption that the driving transistor D-Tr and the light emitting transistor E-Tr shown are n-channel TFTs, but this is an example and the driving transistor D-Tr or the light emitting transistor E-Tr may also be implemented as a p-channel TFT.

The driving transistor D-Tr may be disposed between the light emitting transistor E-Tr and a line to which the high potential voltage EVDD is applied. The driving transistor D-Tr may drive the light emitting element 200 by adjusting the amount of a current Iled flowing into the light emitting element 200 in response to a gate-to-source voltage Vgs. In the case of an n-channel transistor, a gate electrode to which a data signal Vdata is applied may be a positive electrode and a source electrode may be a negative electrode because carriers are electrons. The driving transistor D-Tr may include a first electrode (e.g., a source electrode) connected to a second electrode of the light emitting transistor E-Tr, a second electrode (e.g., a drain electrode) to which the high potential voltage EVDD is applied, and a gate electrode to which the data signal Vdata is applied.

The light emitting transistor E-Tr may be disposed between the driving transistor D-Tr and the light emitting element 200. The light emitting transistor E-Tr may switch the current Iled flowing to the light emitting element 200 at a set pulse width. The light emitting transistor E-Tr may include a first electrode (e.g., a source electrode) connected to the light emitting element 200, a second electrode (e.g., a drain electrode) connected to the first electrode of the driving transistor D-Tr, and a gate electrode to which a light emitting control signal EM is applied.

The pixel driving circuit 204 may cause the light emitting element 200 to emit light in a first control mode or a second control mode. The light emitting element 200 may emit light by being controlled in the first control mode or the second control mode.

When the light emitting element 200 is controlled in the first control mode, luminance of the light emitting element 200 may be controlled by the data signal Vdata in an analog form that is applied to the gate electrode of the driving transistor D-Tr. Since the amount of current Iled flowing to the light emitting element 200 may be adjusted according to the gate-to-source voltage Vgs of the driving transistor D-Tr, luminance of the light emitting element 200 controlled in the first control mode may be adjusted by the data signal Vdata applied to the gate electrode.

When the light emitting element 200 is controlled in the second control mode, luminance of the light emitting element 200 may be controlled by the light emitting control signal EM in a digital form that is applied to the gate electrode of the light emitting transistor E-Tr. For example, the light emitting control signal EM may be a signal in which the width of the pulse is modulated (pulse width modulation (PWM)). The light emitting control signal EM of the digital form may include a duty ratio as the PWM signal. Since the amount of the current Iled applied to the light emitting element 200 may be adjusted by adjusting the duty ratio of the light emitting control signal EM of the digital form, luminance of the light emitting element 200 may be controlled by the light emitting control signal EM.

Referring to FIGS. 7 and 8 described above, the light emitting element 200 may emit light in the first control mode in the (a) section, and may emit light in the second control mode at the (b) point (or section).

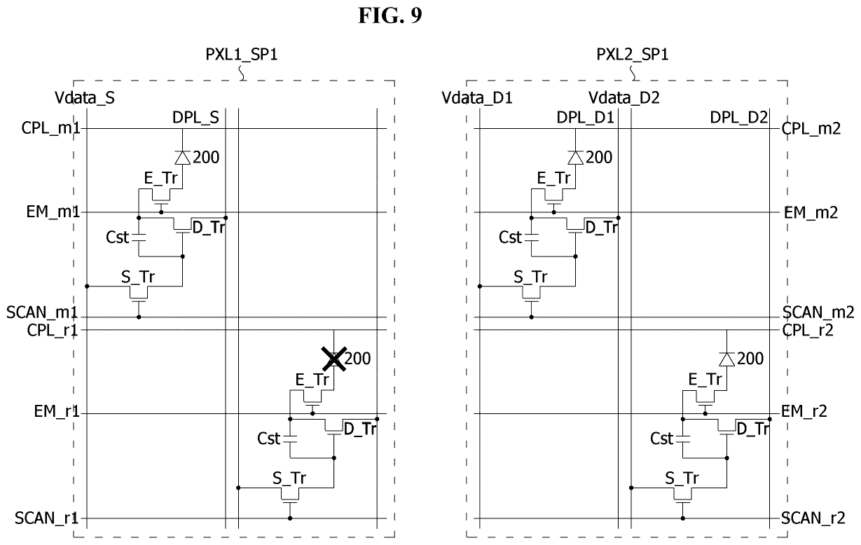

FIG. 9 is a circuit diagram specifically showing a pixel driving circuit according to an aspect of the present disclosure.

Referring to FIG. 9, the display panel may include a first pixel PXL1 and a second pixel PXL2. The first pixel PXL1 may include a 1-1 sub-pixel PXL1_SP1. The second pixel PXL2 may include a 2-1 sub-pixel PXL2_SP1. The 1-1 sub-pixel PXL1_SP1 included in the first pixel PXL1 and the 2-1 sub-pixel PXL2_SP1 included in the second pixel PXL2 may implement the same color. The colors implemented in the sub-pixels PXL1_SP1 and PXL2_SP1 may be any one selected from the group composed of red, green, and blue.

Each of the sub-pixels PXL1_SP1 and PXL2_SP1 may include a single or plurality of pixel driving circuits. As shown, both the 1-1 sub-pixel PXL1_SP1 and the 2-1 sub-pixel PXL2_SP1 include a plurality of pixel driving circuits, but are not limited thereto.

When the sub-pixel includes a single pixel driving circuit, a transfer may not be performed normally and the pixel driving circuit may not be deposited normally.

When the sub-pixels PXL1_SP1 and PXL2_SP1 include a plurality of pixel driving circuits, all of the plurality of pixel driving circuits may not be considered to drive the light emitting elements that operate normally. For example, the 1-1 sub-pixel PXL1_SP1 may include the plurality of pixel driving circuits, one of which may be a pixel driving circuit driving the light emitting element 200 that operates normally, and another may be a pixel driving circuit driving the light emitting element 200 that operates abnormally. The abnormally operating light emitting element 200 is a defective element that fails to emit light even when driving power is applied and is marked with an “X” in the drawing.

The 1-1 sub-pixel PXL1_SP1 may include a single light emitting element which is transferred and operated normally. The 1-1 sub-pixel PXL1_SP1 may be a single chip sub-pixel.

The 2-1 sub-pixel PXL2_SP1 may include dual light emitting elements which are transferred and operated normally. The 2-1 sub-pixel PXL2_SP1 may be a dual chip sub-pixel. One of the plurality of pixel driving circuits may drive the main light emitting element 200 and another may drive the auxiliary light emitting element 200.

The term “single” or “dual” above does not distinguish between the number of pixel driving circuits deposited, but rather refers to the number of LED chips that are transferred and deposited normally, and furthermore operate normally.

The plurality of pixel driving circuits may be connected to each other by a plurality of data lines Vdata_S, Vdata_D1 and Vdata_D2, a plurality of driving power lines DPL_S, DPL_D1, and DPL_D2, a plurality of common power lines CPL_m and CPL_r, a plurality of light emitting control lines EM_m and EM_r, and a plurality of gate lines SCAN_m and SCAN_r.

The plurality of pixel driving circuits may include a plurality of switching elements S_Tr, D_Tr, and E_Tr. The plurality of switching elements S_Tr, D_Tr, and E_Tr shown are implemented as n-channel TFTs, but this is an example and the plurality of switching elements S_Tr, D_Tr and E_Tr may be implemented as p-channel TFTs. A plurality of electrodes (e.g., a first electrode or a second electrode) included in each switching element may be a source electrode or a drain electrode as described above, but may also be the drain electrode or the source electrode.

Each of the plurality of pixel driving circuits may include a switching transistor S_Tr which applies the data signal Vdata to the driving transistor D_Tr in accordance with a gate signal, a driving transistor D_Tr which supplies driving current in accordance with the data signal Vdata applied from the switching transistor S_Tr, a light emitting transistor E_Tr which determines a light emitting timing of the light emitting element 200 in accordance with the light emitting control signal EM, and the light emitting element 200. Each of the plurality of pixel driving circuits may further include a storage capacitor Cst that turns on the driving transistor D_Tr by storing a voltage corresponding to the data signal Vdata.

The plurality of data lines Vdata_S, Vdata_D1, and Vdata_D2 may include a single data line Vdata_S applying the data signal Vdata to the 1-1 sub-pixel PXL1_SP1 including one light emitting element that operates normally, and dual data lines Vdata_D1 and Vdata_D2 applying the data signal Vdata to the 2-1 sub-pixel PXL2_SP1 including a plurality of light emitting elements that operates normally. The dual data lines Vdata_D1 and Vdata_D2 may include a first dual data line Vdata_D1 supplying the data signal Vdata to drive the main light emitting element 200 and a second dual data line Vdata_D2 supplying the data signal Vdata to drive the auxiliary light emitting element 200.

The single data line Vdata_S, the first dual data line Vdata_D1, and the second dual data line Vdata_D2 may all operate independently of each other. For example, a data voltage applied through the single data line Vdata_S, a data voltage applied through the first dual data line Vdata_D1, and a data voltage applied through the second dual data line Vdata_D2 may be different.

The plurality of driving power lines DPL_S, DPL_D1 and DPL_D2 may include a single driving power line DPL_S that applies driving power to the 1-1 sub-pixel PXL1_SP1 including one light emitting element that operates normally, and dual driving power lines DPL_D1 and DPL_D2 that apply driving power to the 2-1 sub-pixel PXL2_SP1 including the plurality of light emitting elements that operate normally. The dual driving power lines DPL_D1 and, DPL_D2 may include a first dual driving power line DPL_D1 which applies driving power to the main light emitting element 200 and a second dual driving power line DPL_D2 which applies driving power to the auxiliary light emitting element 200.

The plurality of common power lines CPL_m and CPL_r may include a first main common power line CPL_m1 that supplies power to the main light emitting element 200 of the 1-1 sub-pixel PXL1_SP1, a second main common power line CPL_m2 that supplies power to the main light emitting element 200 of the 2-1 sub-pixel PXL2_SP1, and a second auxiliary main common power line CPL_r2 that supplies power to the auxiliary light emitting element 200 of the 2-1 sub-pixel PXL2_SP1.

The first main common power line CPL_m1 and the second main common power line CPL_m2 may be connected to or separated from each other. For example, when the 1-1 sub-pixel PXL1_SP1 and the 2-1 sub-pixel PXL2_SP1 share a gate line with each other and are disposed on the same pixel line, the first main common power line CPL_m1 and the second main common power line CPL_m2 may be connected to each other. When the 1-1 sub-pixel PXL1_SP1 and the 2-1 sub-pixel PXL2_SP1 have different gate lines and are disposed on different pixel lines, the first main common power line CPL_m1 and the second main common power line CPL_m2 may be separated from each other.

The plurality of light emitting control lines EM_m and EM_r may include a first main light emitting control line EM_m1 that supplies the light emitting control signal EM to the emitting transistor E_Tr connected to the main light emitting element 200 of the 1-1 sub-pixel PXL1_SP1, a second main light emitting control line EM_m2 that supplies the light emitting control signal EM to the emitting transistor E_Tr connected to the main light emitting element 200 of the 2-1 sub-pixel PXL2_SP1, and a second auxiliary light emitting control line EM_r2 that supplies the light emitting control signal EM to the light emitting transistor E_Tr connected to the auxiliary light emitting element 200 of the 2-1 sub-pixel PXL2_SP1.

The first main light emitting control line EM_m1 and the second main light emitting control line EM_m2 may be connected to or separated from each other. For example, when the 1-1 sub-pixel PXL1_SP1 and the 2-1 sub-pixel PXL2_SP1 share a gate line with each other and are disposed on the same pixel line, the first main light emitting control line EM_m1 and the second main light emitting control line EM_m2 may be connected to each other. When the 1-1 sub-pixel PXL1_SP1 and the 2-1 sub-pixel PXL2_SP1 have different gate lines and are disposed on different pixel lines, the first main light emitting control line EM_m1 and the second main light emitting control line EM_m2 may be separated from each other.

When the first main light emitting control line EM_m1 and the second main light emitting control line EM_m2 are connected to each other, the light emitting transistor E_Tr connected to the main light emitting element 200 of the 1-1 sub-pixel PXL1_SP1 and the light emitting transistor E_Tr connected to the main light emitting element 200 of the 2-1 sub-pixel PXL2_SP1 that share the main light emitting control line EM_m may operate dependently on each other. For example, the duty ratio of the light emitting control signal EM supplied to the first main light emitting control line EM_m1 and the duty ratio of the light emitting control signal EM supplied to the second main light emitting control line EM_m2 may be substantially the same.

The main light emitting control line EM_m and the auxiliary light emitting control line EM_r may operate independently of each other. For example, the duty ratio of the light emitting control signal EM supplied to the main light emitting control line EM_m and the duty ratio of the light emitting control signal EM supplied to the auxiliary light emitting control line EM_r may differ.

The independent operation of the main light emitting control line EM_m and the auxiliary light emitting control line EM_r may be interpreted as the anode electrodes of the light emitting elements 200 being formed independently of each other. Since the anode electrodes are formed independently, voltages supplied to the anode electrodes may be independent in the main light emitting element 200 and the auxiliary light emitting element 200.

The plurality of gate lines SCAN_m and SCAN_r may include a first main gate line SCAN_m1 that supplies the gate signal to drive the main light emitting element 200 of the 1-1 sub-pixel PXL1_SP1, a second main gate line SCAN_m2 that supplies that the gate signal to drive the main light emitting element 2000 of the 2-1 sub-pixel PXL2_SP1, and an auxiliary gate line SCAN_r that supplies the gate signal to drive the auxiliary light emitting element 200 of the 2-1 sub-pixel PXL2_SP1.

The first main gate line SCAN_m1 and the second main gate line SCAN_m2 may be connected to or separated from each other. For example, when the 1-1 sub-pixel PXL1_SP1 and the 2-1 sub-pixel PXL2_SP1 share a gate line with each other and are disposed on the same pixel line, the first main gate line SCAN_m1 and the second main gate line SCAN_m2 may be connected to each other. When the 1-1 sub-pixel PXL1_SP1 and the 2-1 sub-pixel PXL2_SP1 have different gate lines and are disposed on different pixel lines, the first main gate line SCAN_m1 and the second main gate line SCAN_m2 may be separated from each other.

The switching transistor S_Tr included in each of the plurality of pixel driving circuits may supply the data voltage to the driving transistor D_Tr or the storage capacitor Cst depending on the gate signal. The switching transistor S_Tr may include a gate electrode connected to the gate lines SCAN_m and SCAN_r to which the gate signal is applied, a first electrode connected to the data lines Vdata_S, Vdata_D1, and Vdata_D2 to which the data signal Vdata is applied, and a second electrode connected to the gate electrode of the driving transistor D_Tr.

The driving transistor D_Tr included in each of the plurality of pixel driving circuits may supply the driving current to the light emitting element 200 depending on a voltage supplied through the switching transistor S_Tr or a voltage supplied through the storage capacitor Cst. The driving transistor D_Tr may include the gate electrode to which the data signal Vdata is applied by connecting to the second electrode of the switching transistor S_Tr, the first electrode to which the driving power is applied, and a second electrode connected to the first electrode (or an emitting node) of the light emitting transistor E_Tr.

The turn-on timing of the light emitting transistor E_Tr included in each of the plurality of pixel driving circuits may be determined by the time according to a pulse width of a signal supplied through the light emitting control lines EM_m and EM_r. The turned-on light emitting transistor E_Tr may supply the driving current applied through the driving transistor D_Tr to the light emitting element 200. The time according to the pulse width may be determined by a duty ratio of the signal supplied through the light emitting control line. The pulse width of the signal supplied through the light emitting control line EM_m and EM_r may be determined by a preset duty ratio. The light emitting transistor E_Tr may include a gate electrode to which the light emitting control signal EM is applied, a first electrode connected to the second electrode (or a light emitting node) of the driving transistor D_Tr, and a second electrode connected to the light emitting element 200.

The data signal Vdata supplied to each of the driving transistors D_Tr may be a pulse amplitude modulation (PAM) signal. A voltage corresponding to the data signal Vdata supplied to each of the driving transistors D_Tr may be the data signal Vdata in the analog form described above.

The light emitting control signal EM supplied to each of the light emitting transistors E_Tr may be a pulse width modulation (PWM) signal. A voltage corresponding to the light emitting control signal EM supplied to each of the light emitting transistors E_Tr may be the light emitting control signal EM in the digital form described above.

When the light emitting element 200 is controlled in the first control mode, luminance may be adjusted by the data signal Vdata in the analog form, and when the light emitting element 200 is controlled in the second control mode, luminance may be adjusted by the light emitting control signal EM in the digital form.

The 1-1 sub-pixel PXL1_SP1, which is a single chip sub-pixel including only the main light emitting element 200, may be driven in the first control mode, the second control mode, and the first control mode in a direction in which a target luminance value increases.

The 2-1 sub-pixel PXL2_SP1, which is a dual chip sub-pixel including the main light emitting element 200 and the auxiliary light emitting element 200, may be driven in the first control mode, the second control mode, and the second control mode in the direction in which the target luminance value increases.

Luminance range of the light emitting element may be divided into a first luminance section LB1, a second luminance section LB2, and a third luminance section LB3 in order from the smallest to the largest. The second luminance section LB2 may have a luminance value greater than a luminance value of the first luminance section LB1. The third luminance section LB3 may have a luminance value greater than the luminance value of the second luminance section LB2.

In the first luminance section LB1, the 1-1 sub-pixel PXL1_SP1, which is a single chip sub-pixel, may be driven in the first control mode, and the 2-1 sub-pixel PXL2_SP1, which is a dual chip sub-pixel, may be driven in the first control mode. In the second luminance section LB2, the 1-1 sub-pixel PXL1_SP1, which is a single chip sub-pixel, may be driven in the second control mode, and the 2-1 sub-pixel PXL2_SP1, which is a dual chip sub-pixel, may be driven in the second control mode. In the third luminance section LB3, the 1-1 sub-pixel PXL1_SP1, which is a single chip sub-pixel, may be driven in the first control mode, and the 2-1 sub-pixel PXL2_SP1, which is a dual chip sub-pixel, may be driven in the second control mode.

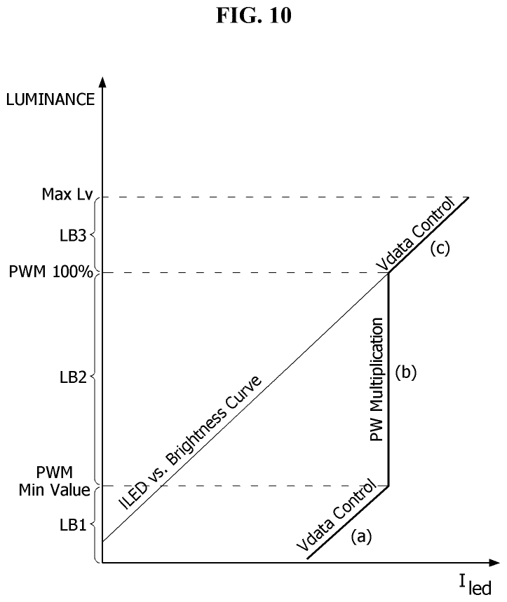

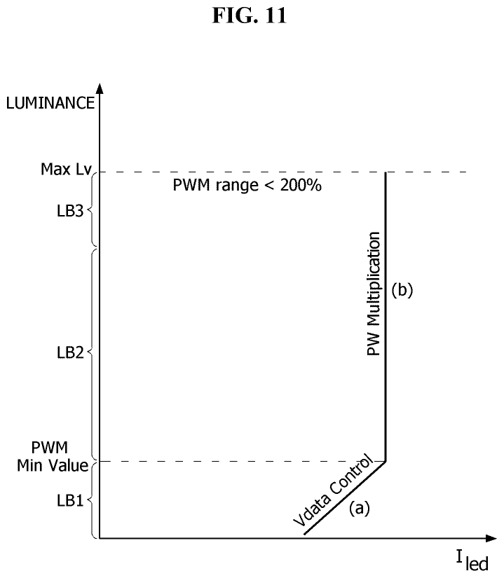

FIG. 10 is a graph showing control modes according to luminance sections in a single chip sub-pixel. FIG. 11 is a graph showing control modes according to luminance sections in a dual chip sub-pixel.

Referring to FIGS. 7, 9 and 10, a target luminance of a section (a) may include the first luminance section LB1. In the section (a), luminance of the light emitting element 200 may be controlled in the first control mode. In the section (a), as a greater current is applied by the driving transistor D_Tr, greater luminance may be implemented. The light emitting control signal EM having a minimum pulse width may be applied at a point having a maximum luminance value in the section (a).

A target luminance of a section (b) may include the second luminance section LB2. In the section (b), luminance of the light emitting element 200 may be controlled in the second control mode. In the section (b), as a signal with a wider pulse width (for example, a signal with a greater duty ratio) is applied to the light emitting transistor E_Tr, greater luminance may be implemented. The light emitting control signal EM with a minimum pulse width may be applied at a point having a minimum luminance value in the section (b). The light emitting control signal EM with a maximum pulse width may be applied at a point having a maximum luminance value in the section (b). The maximum pulse width may be a signal with a duty ratio of 100%.

A target luminance of a section (c) may include the third luminance section LB3. In the section (c), luminance of the light emitting element 200 may be controlled in the first control mode. In the section (c), as a greater current is applied by the driving transistor D_Tr, greater luminance may be implemented. In the section (c), EQE of the emitting element (200) may not be maximum. In the section (c), a data voltage higher than the data voltage supplied in the section (a) with efficiency less than the maximum EQE may be applied to the main light emitting element 200 of the 1-1 sub-pixel PXL1_SP1.

Referring to FIGS. 7, 9 and 11, a target luminance of a section (a) may include the first luminance section LB1. In the section (a), luminance of the light emitting element 200 may be controlled in the first control mode. In the section (a), as a greater current is applied by the driving transistor D_Tr, greater luminance may be implemented.

A target luminance of a section (b) may include the second luminance section LB2 and the third luminance section LB3. The target luminance of the section (b) may include the target luminance of the section (b) and the target luminance of the section (c) of FIG. 10 described above. In the section (b), luminance of the light emitting element 200 may be controlled in the second control mode. In the section (b), as a signal with a wider pulse width (for example, a signal with a greater duty ratio) is applied to the light emitting transistor E_Tr, greater luminance may be implemented. The light emitting control signal EM with a minimum pulse width may be applied at a point having a minimum luminance value in the section (b). The light emitting control signal EM with a maximum pulse width may be applied at a point having a maximum luminance value in the section (b). The maximum pulse width may be a signal with a duty ratio of 100%.

Referring to FIGS. 9 to 11, the display device according to an aspect may include the 1-1 sub-pixel PXL1_SP1, which is a single chip sub-pixel including the main light emitting element 200, and the 2-1 sub-pixel PXL2_SP1, which is a dual chip including the main light emitting element 200 and the auxiliary light emitting element 200.

In the first luminance section LB1, the main light emitting element 200 of the 1-1 sub-pixel PXL1_SP1 may be controlled by the single data line Vdata_S, the main light emitting element 200 of the 2-1 sub-pixel PXL2_SP1 may be controlled by the first dual data line Vdata_D1, and the auxiliary light emitting element 200 of the 2-1 sub-pixel PXL2_SP1 may be controlled by the second dual data line Vdata_D2. In the first luminance section LB1, the magnitude of the data voltage supplied through the single data line Vdata_S, the first dual data line Vdata_D1, or the second dual data line Vdata_D2 may be adjusted to increase the luminance of the 1-1 sub-pixel PXL1_SP1 and/or the 2-1 sub-pixel PXL2_SP1. Alternatively, a duty ratio of the light emitting control signal supplied by the auxiliary light emitting control line EM_r may be adjusted to increase the luminance of the 2-1 sub-pixel PXL2_SP1.

A data voltage value required to implement the maximum target luminance in the first luminance section LB1 when controlling the 1-1 sub-pixel PXL1_SP1 in the first control mode and a data voltage value required to implement the maximum target luminance in the first luminance section LB1 when controlling the 2-1 sub-pixel PXL2_SP1 in the first control mode may be substantially the same. However, the present disclosure is not limited thereto, and in the 2-1 sub-pixel PXL2_SP1, the maximum target luminance in the first luminance section LB1 may be implemented by supplying a data voltage to the second dual data line Vdata_D2 in addition to the first dual data line Vdata_D1. In this case, the sum of the data voltage supplied to the first dual data line Vdata_D1 and the data voltage supplied to the second dual data line Vdata_D2 may differ from the data voltage supplied to the single data line Vdata_S.

In the second luminance section LB2, a data voltage corresponding to the maximum EQE may be supplied to the main light emitting element 200 of the 1-1 sub-pixel PXL1_SP1, which is a single chip sub-pixel. In the second luminance section LB2, the duty ratio of the main light emitting control line EM_m may be adjusted to increase the luminance of the main light emitting element 200 of the 1-1 sub-pixel PXL1_SP1, which is a single chip sub-pixel. In the second luminance section LB2, the luminance of the main light emitting element 200 of the 1-1 sub-pixel PXL1_SP1, which is a single chip sub-pixel, may be controlled by the main light emitting control line EM_m.

In the second luminance section LB2, a data voltage corresponding to the maximum EQE may be supplied to the main light emitting element 200 of the 2-1 sub-pixel PXL2_SP1, which is a dual chip sub-pixel. In the second luminance section LB2, the duty ratio of the main light emitting control line EM_m may be adjusted to increase the luminance of the main light emitting element 200 of the 2-1 sub-pixel PXL2_SP1. In the second luminance section LB2, the main light emitting element 200 of the 2-1 sub-pixel PXL2_SP1, which is a dual chip sub-pixel, may be controlled by the main light emitting control line EM_m which simultaneously controls the luminance of the main light emitting element 200 of the 1-1 sub-pixel PXL1_SP1, which is a single chip sub-pixel.

In the second luminance section LB2, a data voltage may be supplied by the second dual data line Vdata_D2, or the light emitting control signal EM supplied by the auxiliary light emitting control line EM_r operating independently with the main light emitting control line EM_m may be supplied to the auxiliary light emitting element 200 of the 2-1 sub-pixel PXL2_SP1, which is a dual chip sub-pixel. In the second luminance section LB2, the magnitude of the data voltage supplied through the second dual data line Vdata_D2 may be adjusted to increase the luminance of the auxiliary light emitting element 200 of the 2-1 sub-pixel PXL2_SP1, which is a dual chip sub-pixel. Alternatively, the duty ratio of the light emitting control signal supplied by the auxiliary light emitting control line EM_r may be adjusted to increase the luminance of the auxiliary light emitting element 200 of the 2-1 sub-pixel PXL2_SP1, which is a dual chip.

In the second luminance section LB2, the luminance of the 2-1 sub-pixel PXL2_SP1, which is a dual chip sub-pixel, may be controlled by the main light emitting control line EM_m, the auxiliary light emitting control line EM_r, and the second dual data line Vdata_D2.

In the third luminance section LB3, the light emitting control signal EM having the maximum pulse width may be applied to the main light emitting element 200 of the 1-1 sub-pixel PXL1_SP1, which is a single chip sub-pixel. In the third luminance section LB3, the magnitude of the data voltage applied through the single data line Vdata_S may be adjusted to increase the luminance of the main light emitting element 200 of the 1-1 sub-pixel PXL1_SP1, which is a single chip sub-pixel. In the third luminance section LB3, a data voltage higher than the data voltage supplied in the first luminance section LB1 with efficiency less than the maximum EQE may be applied to the main light emitting element 200 of the 1-1 sub-pixel PXL1_SP1, which is a single chip sub-pixel.

In the third luminance section LB3, the light emitting control signal EM having the maximum pulse width may be applied to the main light emitting element 200 of the 2-1 sub-pixel PXL2_SP1, which is a dual-chip sub-pixel, by the main light emitting control line EM_m which simultaneously controls the luminance of the main light emitting element 200 of the 1-1 sub-pixel PXL1_SP1, which is a single-chip sub-pixel. In this case, a data voltage may be supplied by the second dual data line Vdata_D2, or the light emitting control signal EM supplied by the auxiliary light emitting control line EM_r operating independently with the main light emitting control line EM_m may be supplied to the auxiliary light emitting element 200 of the 2-1 sub-pixel PXL2_SP1, which is a dual chip sub-pixel. To implement the maximum target luminance in the third luminance section LB3, the light emitting control signal EM supplied by the auxiliary light emitting control line EM_r may be supplied to the auxiliary light emitting element 200 of the 2-1 sub-pixel PXL2_SP1, which is a dual chip sub-pixel. In this case, the light emitting control signal EM may have the maximum pulse width.

In the third luminance section LB3, although the light emitting control signal EM with the maximum pulse width is supplied to the auxiliary light emitting element 200 of the 2-1 sub-pixel PXL2_SP1 through the auxiliary light emitting control line EM_r, when the 2-1 sub-pixel PXL2_SP1 fails to implement the maximum target luminance, a data voltage higher than the data voltage supplied in the first luminance section LB1 with efficiency less than the maximum EQE may be applied as well. In this case, the amount of decrease in the EQE of the data voltage supplied to the auxiliary light emitting element 200 of the 2-1 sub-pixel PXL2_SP1 may be less than the amount of decrease in the EQE of the data voltage supplied to the main light emitting element 200 of the 1-1 sub-pixel PXL1_SP1. The overall luminous efficiency of the 2-1 sub-pixel PXL2_SP1 may be increased.

In the luminance section LB3, the average value of the EQE of the main light emitting element and the EQE of the auxiliary light emitting element included in the 2-1 sub-pixel PXL2_SP1 may be greater than the EQE of the 1-1 sub-pixel PXL1_SP1.

According to an aspect, the luminous efficiency of the display device including the 1-1 sub-pixel PXL1_SP1 and the 2-1 sub-pixel PXL2_SP1 may be increased overall. The display device may have a reduced power consumption and be driven with low power. In addition, it is possible to increase a lifetime and enhance light extraction characteristics.

The display device according to the aspects of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation system, an in-vehicle display device, a theater display device, a television, a wallpaper device, a signage device, a game device, a laptop, a monitor, a camera, a camcorder, a household appliance, etc. In addition, the display device according to one or more aspects of the present disclosure may be applied to an organic light emitting lighting device or an inorganic light emitting lighting device.

In the display device according to the present disclosure, it is possible to increase light efficiency by utilizing both a main light emitting element and an auxiliary light emitting element. In addition, the display device may have a reduced power consumption as light efficiency increases.

The effects of the present disclosure are not limited to those mentioned above, and other effects not mentioned will be clearly understood by those skilled in the art from description of the claims.

Since the content of the disclosure described in the problem to be solved, means of solving the problem, and objects above do not specify the essential features of the claims, the scope of the claims is not limited by the matters described in the content of the disclosure.

Although aspects of the present disclosure have been described in more detail with reference to the accompanying drawings, the present disclosure is not necessarily limited to the aspects, and various modifications may be carried out without departing from the technical spirit of the present disclosure. Therefore, the aspects disclosed in the present disclosure are not intended to limit the technical spirit of the present disclosure but are for illustrative purposes, and the scope of the technical spirit of the present disclosure is not limited by these aspects. Thus, it is intended that the present disclosure covers the modifications and variations of the aspects provided they come within the scope of the appended claims and their equivalents.

What is claimed is:

1. A display device comprising:
a first sub-pixel including a first light emitting element and a first pixel driving circuit that drives the first light emitting element; and
a second sub-pixel including a second light emitting element, a second pixel driving circuit that drives the second light emitting element, a third light emitting element and a third pixel driving circuit that drives the third light emitting element,
wherein the first pixel driving circuit controls the first light emitting element to emit light in a first control mode, when a target luminance of the first sub-pixel is included in a high luminance section, and
wherein the second pixel driving circuit controls the second light emitting element to emit light in a second control mode, when a target luminance of the second sub-pixel is included in the high luminance section.

2. The display device of claim 1, wherein a magnitude of a data signal is changed to adjust a luminance of a light emitting element, in the first control mode, and
wherein the magnitude of the data signal is maintained, in the second control mode.

3. The display device of claim 1, wherein the first sub-pixel and the second sub-pixel implement the same color.

4. The display device of claim 2, wherein the first pixel driving circuit controls the first light emitting element to emit light in the first control mode, when the target luminance of the first sub-pixel is included in a low luminance section, and
wherein the second pixel driving circuit controls the second light emitting element to emit light in the first control mode, when the target luminance of the second sub-pixel is included in the low luminance section.

5. The display device of claim 4, wherein the first pixel driving circuit controls the first light emitting element to emit light in the second control mode and adjusts a luminance of the first light emitting element by changing an emission time of the first light emitting element, when the target luminance of the first sub-pixel is included in a medium luminance section between the low luminance section and the high luminance section, and
wherein the second pixel driving circuit controls the second light emitting element to emit light in the second control mode and adjusts a luminance of the second light emitting element by changing an emission time of the second light emitting element, when the target luminance of the second sub-pixel is included in the medium luminance section.

6. The display device of claim 5, wherein at least one of the first light emitting element and the second light emitting element has a maximum external quantum efficiency (EQE) in the medium luminance section.

7. The display device of claim 6, wherein, in the second control mode, the magnitude of the data signal is maintained to correspond to the maximum external quantum efficiency.

8. The display device of claim 1, wherein the third pixel driving circuit controls the third light emitting element to emit light, when the target luminance of the second sub-pixel is included in the high luminance section.

9. The display device of claim 8, wherein the third pixel driving circuit adjusts a luminance of the third light emitting element by changing a magnitude of a data signal.

10. The display device of claim 8, wherein the third pixel driving circuit adjusts a luminance of the third light emitting element by changing an emission time of the third light emitting element.

11. The display device of claim 5, wherein each of the first pixel driving circuit, the second pixel driving circuit and the third pixel driving circuit includes:
a driving transistor which supplies a driving circuit for driving the light emitting element based on the data signal; and
a light emitting transistor which applies the driving current to the light emitting element based on a light emitting control signal.

12. The display device of claim 11, wherein the data signal includes a pulse amplitude modulation signal in an analog form, and
wherein the light emitting control signal includes a pulse width modulation signal in a digital form.

13. The display device of claim 12, wherein the light emitting control signal having a minimum pulse width is applied to the first pixel driving circuit when the target luminance of the first sub-pixel is a maximum luminance of the low luminance section, and
wherein the light emitting control signal having the minimum pulse width is applied to the second pixel driving circuit when the target luminance of the second sub-pixel is the maximum luminance of the low luminance section.

14. The display device of claim 12, wherein the light emitting control signal having a minimum pulse width is applied to the first pixel driving circuit when the target luminance of the first sub-pixel is a minimum luminance of the medium luminance section, and
wherein the light emitting control signal having the minimum pulse width is applied to the second pixel driving circuit when the target luminance of the second sub-pixel is the minimum luminance of the medium luminance section.

15. The display device of claim 12, wherein the light emitting control signal having a maximum pulse width is applied to the first pixel driving circuit when the target luminance of the first sub-pixel is a maximum luminance of the medium luminance section.

16. The display device of claim 15, wherein the light emitting control signal having the maximum pulse width includes a duty ratio of 100%.

17. The display device of claim 15, wherein the light emitting control signal having the maximum pulse width is applied to the first pixel driving circuit when the target luminance of the first sub-pixel is included in the high luminance section.

18. The display device of claim 12, wherein the light emitting control signal having a maximum pulse width is applied to the second pixel driving circuit when the target luminance of the second sub-pixel is a maximum luminance of the high luminance section.

19. The display device of claim 12, wherein a duty ratio of the light emitting control signal applied to the first pixel driving circuit increases as the target luminance of the first sub-pixel increases when the target luminance of the first sub-pixel is included in the medium luminance section, and
wherein a duty ratio of the light emitting control signal applied to the second pixel driving circuit increases as the target luminance of the second sub-pixel increases when the target luminance of the second sub-pixel is included in the medium luminance section.

20. The display device of claim 11, wherein the first pixel driving circuit and the second pixel driving circuit are applied with a same light emitting control signal.

21. The display device of claim 8, wherein, in the high luminance section, an average value of the external quantum efficiencies of the second light emitting element and the third light emitting element included in the second pixel driving circuit is greater than the external quantum efficiency of the first light emitting element included in the first pixel driving circuit.

22. The display device of claim 1, wherein at least one of the first light emitting element, the second light emitting element and the third light emitting element includes an inorganic light emitting diode (LED).
